(19) United States
(12) Patent Application Publication
(10) Pub. No.: US 2014/0374266 A1
(43) Pub. Date: Dec. 25, 2014

(54) METHOD AND APPARATUS FOR FORMING A CADMIUM ZINC TELLURIDE LAYER IN A PHOTOVOLTAIC DEVICE

(71) Applicant: First Solar, Inc., Perrysburg, OH (US)

(72) Inventors: Markus Gloeckler, Perrysburg, OH (US); Long Cheng, Perrysburg, OH (US)

(73) Assignee: First Solar, Inc., Perrysburg, OH (US)

(21) Appl. No.: 14/136,570

(22) Filed: Dec. 20, 2013

Related U.S. Application Data
(60) Provisional application No. 61/746,860, filed on Dec. 28, 2012.

(51) Int. Cl. C25D 7/12; C25D 17/00; H01L 31/18; C25D 21/12

(52) U.S. Cl. CPC C25D 7/12; C25D 21/12; C25D 17/001; H01L 31/1832
USPC 205/102; 205/157; 204/228.8

(57) ABSTRACT

A method and apparatus for controlling and changing the composition of a cadmium zinc telluride (CZT) transition layer as it is formed over a partially completed photovoltaic device using electrochemical deposition (ECD) where plating variables are systematically changed while the CZT transition layer is formed to change the composition of the plated CZT transition layer.

This application claims the benefit of priority of U.S. Provisional Patent Application No. 61/746,860, filed Dec. 28, 2012, entitled: “Method and Apparatus for Forming a Cadmium Zinc Telluride Layer in a Photovoltaic Device” the entirety of which is incorporated by reference herein.

### FIELD OF THE INVENTION

Disclosed embodiments relate generally to methods and apparatuses for manufacturing photovoltaic devices including photovoltaic cells and photovoltaic modules, and more particularly, to a method and apparatus for controlling the composition of cadmium zinc telluride thin film layers during formation of photovoltaic devices.

### BACKGROUND OF THE INVENTION

Photovoltaic devices are becoming increasingly popular for providing renewable energy. FIG. 1 shows one example of a photovoltaic device 100, which can be formed by depositing sequential thin film layers on a substrate 110. The photovoltaic device 100 may include a TCO stack 170 formed over the substrate 110, semiconductor layers 180 formed over the TCO stack 170, a back contact 155 formed over semiconductor layers 180 and a back support 160 formed on the back contact 155.

Generally, the substrate 110 is the outermost layer of a completed photovoltaic device 100 and, in use, may be exposed to a variety of temperatures and forms of precipitation, such as rain, snow, sleet, and hail. The substrate 110 may also be the first layer that incident light encounters upon reaching the photovoltaic device 100. It is therefore desirable to select a material for the substrate 110 that is both durable and highly transparent. For these reasons, the substrate 110 may include, for example, borosilicate glass, soda lime glass, or float glass.

The TCO stack 170 may include a barrier layer 115 formed on the substrate 110 for preventing sodium diffusion from the substrate 110 into the photovoltaic device. The barrier layer 115 may be formed of, for example, silicon nitride, silicon oxide, aluminum-doped silicon oxide, boron-doped silicon nitride, phosphorus-doped silicon nitride, silicon oxide-nitride, or any combination or alloy thereof. The TCO stack 170 further includes a TCO layer 120 formed on the barrier layer 115. The TCO layer 120 functions as the first of two electrodes of the photovoltaic device 100 and may be formed of, for example, fluorine doped tin oxide, cadmium stannate, or cadmium tin oxide. In addition, the TCO stack 170 includes a buffer layer 125 formed on the TCO layer 120 to provide a smooth surface for semiconductor material deposition. The buffer layer 120 may be formed of, for example, tin oxide (e.g., a tin (IV) oxide), zinc tin oxide, zinc oxide, zinc oxysulfide, and zinc magnesium oxide. It is possible to omit one or both of the barrier layer 115 and buffer layer 120 in the TCO stack 170 if desired.

Back contact 155 functions as the second of the two electrodes and may be made of one or more highly conductive materials, for example, molybdenum, aluminum, copper, silver, gold, or any combination thereof, providing a low-resistance ohmic contact. TCO layer 120 and back contact 155 are used to transport photocurrent away from photovoltaic device 100. Back support 160, which may be glass, is formed on back contact 155 to protect photovoltaic device 100 from external hazards.

The semiconductor layers 180 may include a semiconductor window layer 130, for example, a cadmium sulfide layer, a semiconductor absorber layer 140, for example, a cadmium telluride layer, a transition semiconductor layer 145, for example, a cadmium zinc telluride layer, and a semiconductor reflector layer 150, for example, a zinc telluride layer. The semiconductor window layer 130 allows the penetration of solar radiation to the semiconductor absorber layer 140 which then converts solar energy to electricity through the formation of minority electron carriers. Specifically, semiconductor materials, like any other solids, have an electronic band structure consisting of a valence band, a conduction band and a band gap separating them. When an electron in the valence band acquires enough energy to jump over the band gap and reach the conduction band, it can flow freely as current. Furthermore, it will also leave behind an electron hole in the valence band that can flow as freely as current. Carrier generation describes processes by which electrons gain energy and move from the valence band to the conduction band, producing two mobile carriers: an electron and a hole; while recombination describes processes by which a conduction band electron loses energy and re-occupies the energy state of an electron hole in the valence band. In a p-type semiconductor material like the semiconductor absorber layer 140, electrons are less abundant than holes, hence they are referred to as minority electron carriers whereas holes are referred to as majority carriers.

During the conversion of solar energy to electricity at the semiconductor absorber layer 140, some minority electron carriers penetrate through the absorber layer 140 and may recombine with hole carriers, causing power dissipation inside the photovoltaic device 100, thereby reducing power conversion efficiency. Semiconductor reflector layer 150 is deposited over the semiconductor absorber layer 140 to act as a barrier or reflector against the minority electron carrier diffusion, which may reduce power dissipation in the photovoltaic device 100. The reflector layer 150 is formed of a semiconductor material with electron affinity lower than that of the absorber layer 140, for example, zinc telluride, which forces electron carrier flow back toward the electron absorber layer 140, minimizing minority electron diffusion. This is described in U.S. Provisional Patent Application 61/547,924, entitled “Photovoltaic Device And Method Of Formation,” filed on Oct. 17, 2011, the disclosure of which is incorporated herein by reference.

Although semiconductor reflector layer 150 reduces power dissipation and increases power conversion efficiency in the photovoltaic device 100, lattice mismatch may occur between the semiconductor reflector layer 150 and the semiconductor absorber layer 140, which can partially negate this benefit. In general, semiconductor materials contain a lattice, or a periodic arrangement of atoms specific to a given material. Lattice mismatching refers to a situation wherein two materials featuring different lattice constants (a parameter defining the unit cell of a crystal lattice, that is, the length of an edge of the cell or an angle between edges) are brought together by deposition of one material on top of another. In general, lattice mismatch can cause misorientation of film growth, film cracking, and creation of point defects at the interface between the two materials featuring the different lattice constants.

To reduce the effects of lattice mismatch between the semiconductor absorber layer 140 and the semiconductor reflector layer 150, the semiconductor transition layer 145, formed of a combination of the semiconductor absorber material and the semiconductor reflector material, for example, a Cd(1-x)Zn(x)Te layer, may be formed between the semiconductor absorber layer 140 and the semiconductor reflector layer 150. By virtue of its composition, the semiconductor transition layer 145 has a lattice constant between that of the semiconductor absorber layer 140 and the semiconductor reflector layer 150, which reduces lattice mismatch between the two layers and increases the electronic conversion efficiency of the photovoltaic device 100.

As the exact composition of the semiconductor transition layer 145 can determine the reduction in lattice mismatch between the semiconductor absorber layer and the semiconductor reflector layer, and ultimately the amount of power dissipation that can be averted, controlling the composition of this layer during formation is extremely important to semiconductor device efficiency. Accordingly, a method and apparatus for precisely controlling and changing the composition of the semiconductor transition layer deposition on the semiconductor absorber layer is desired.

### BRIEF DESCRIPTION OF THE DRAWINGS

FIG. 1 is a schematic of a photovoltaic device having multiple thin film layers;

FIG. 2 is a schematic of a CZT transition layer formed over a partially completed photovoltaic device;

FIGS. 3A-3B illustrate two possible mole fraction profiles for CZT transition layers in various photovoltaic device configurations;

FIG. 4 illustrates a schematic of an ECD unit for forming a CZT transition layer over a partially completed photovoltaic device;

FIG. 5 illustrates a flow chart of an ECD plating process where ECD bias voltage is changed during plating of a CZT transition layer over a partially completed photovoltaic device;

FIG. 6 illustrates a flow chart of an ECD plating process where plating current density is changed during plating of a CZT transition layer over a partially completed photovoltaic device;

FIG. 7 illustrates a flow chart of an ECD plating process where plating bath temperature is changed during plating of a CZT transition layer over a partially completed photovoltaic device;

FIG. 8 illustrates a schematic of an ECD system having two ECD units for forming a CZT transition layer over a partially completed photovoltaic device;

FIG. 9 illustrates a flow chart of an ECD plating process where a CZT transition layer is formed using multiple plating baths with different plating solutions;

FIG. 10 illustrates a flow chart of an ECD plating process where a CZT transition layer is formed using multiple plating baths with different plating solutions and the plating current density is changed during the plating of different portions of the CZT transition layer over a partially completed photovoltaic device.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

Disclosed herein are embodiments of a method and apparatus for controlling and changing the composition of a cadmium zinc telluride (CZT) semiconductor transition layer while the layer is being deposited. In this case, an electrochemical deposition (ECD) process is used to form the layer. The method includes beginning the ECD process using one set of variables and then systematically changing at least one, or a few or all the variables, in a step-wise, gradual or random fashion, while the CZT transition layer is being deposited to effectively control the composition of the layer.

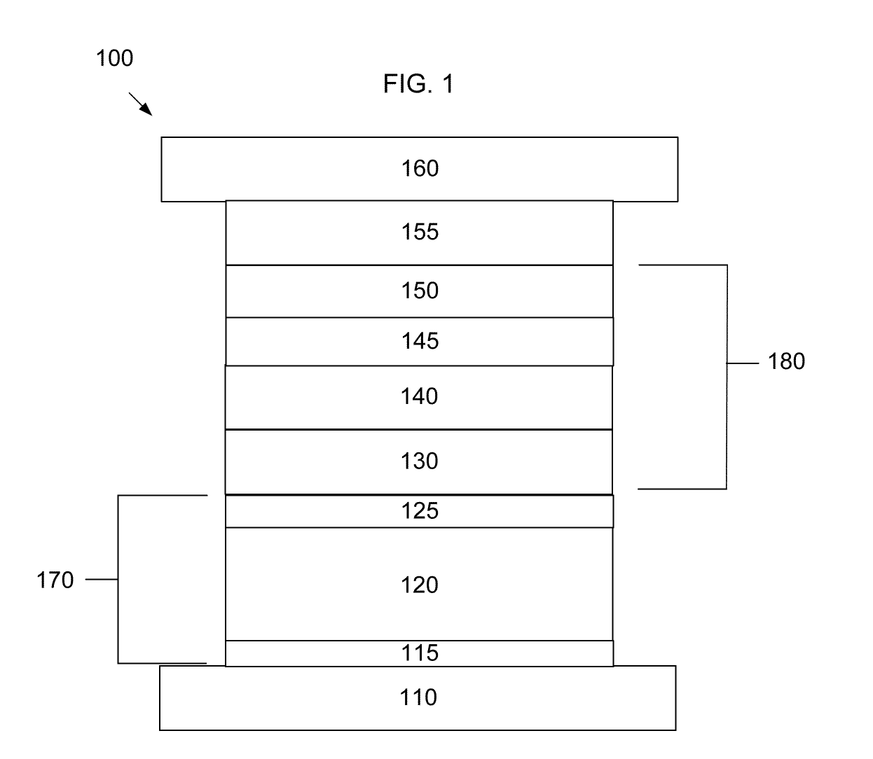

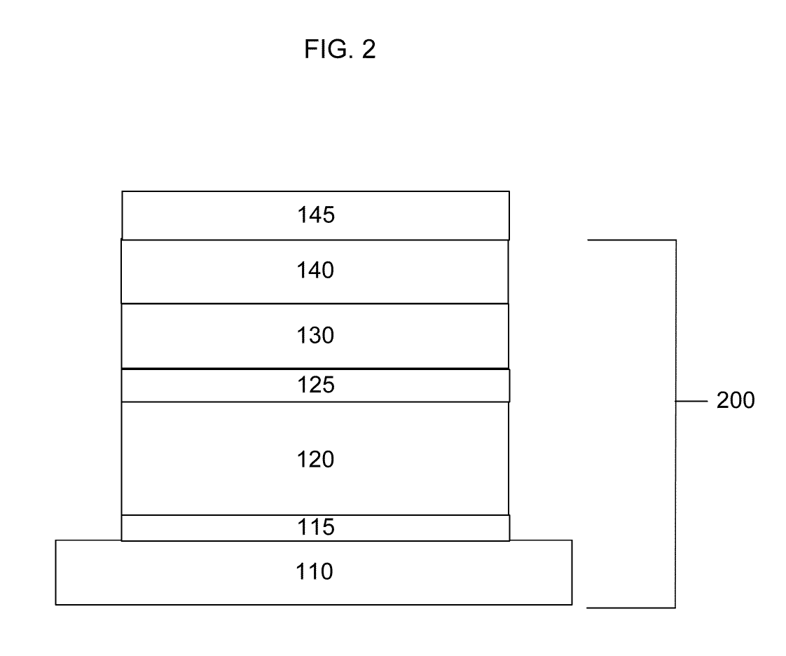

ECD may deposit a CZT semiconductor transition layer on partially completed photovoltaic devices having multiple thin-film layers previously deposited on a substrate. For example, FIG. 2 shows a CZT transition layer 145 deposited on a partially completed photovoltaic device 200. The partially completed photovoltaic device 200 includes a substrate 110 and thin film layers 115, 120, 125, 130, 140 deposited sequentially on the substrate 110 as described in reference to the example photovoltaic device 100 shown in FIG. 1. The CZT transition layer 145 may be formed on the semiconductor absorber layer 140. The CZT transition layer 145 may be formed of one or several Cd(1-x)Zn(x)Te layers where x defines any suitable number between 0 and 1 and the zinc/cadmium mole ratio increases either step-wise or gradually as it gets farther from the semiconductor absorber layer 140.

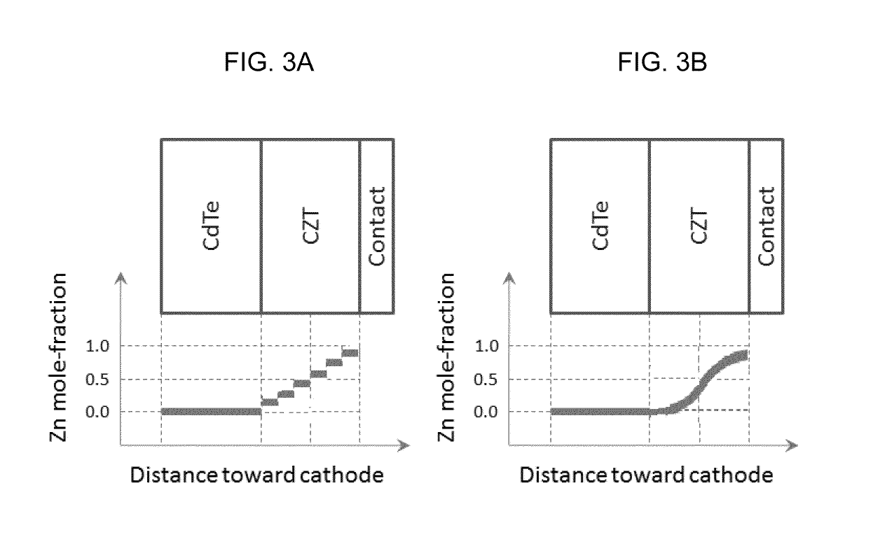

FIGS. 3A and 3B illustrate two possible zinc/cadmium mole-fraction profiles of two example CZT transition layers 145 formed on a semiconductor absorber layer 140. FIG. 3A depicts a 0 to 1 step-wise increase of a zinc mole-fraction in the CZT transition layer 145, moving away from the semiconductor absorber layer 140. FIG. 3B depicts a 0 to 1 gradual increase (as opposed to the step-wise representation in FIG. 3A) of a zinc-mole fraction in the CZT transition layer 145, moving away from the semiconductor absorber layer 140. It should be noted that FIGS. 3A and 3B are only examples of possible zinc/cadmium mole-fraction profiles that may be used and that the CZT transition layer 145 can have any desired mole-fraction profile.

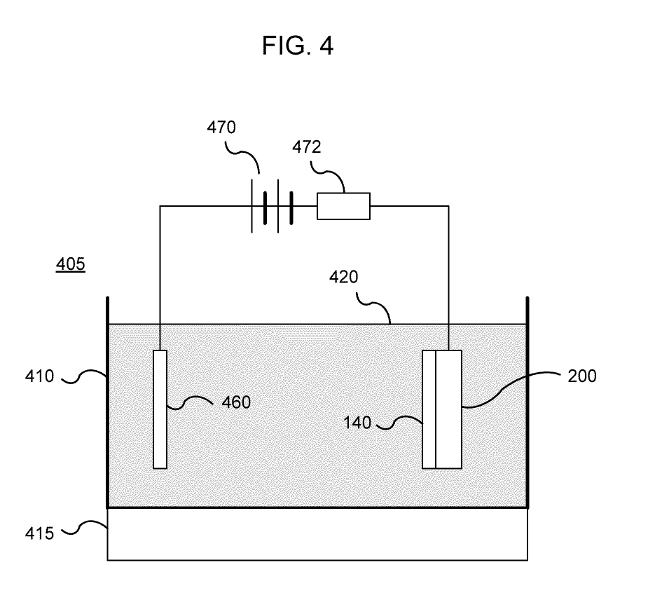

FIG. 4 illustrates an ECD unit 405 for forming a CZT transition layer 145 over a partially completed photovoltaic device 200 as shown in FIG. 2. ECD unit 405 may include a container 410, a heater 415 and plating solution 420 in the container 410. The heater 415 may be located under or around the container 410. The heater 415 may also be attached or detached from the container 410. When plating solution 420 is in contact with partially completed photovoltaic device 200, the photovoltaic device 200 becomes electrically connected to power source 470. As with all power sources, power source 470 has a positive terminal and a negative terminal. The partially completed photovoltaic device 200 is most often connected to the negative terminal of the power source 470 and acts as a cathode in the ECD unit 405. A complementary electrode 460 which may be made of any appropriate electrode material known in the art, for example, carbon, stainless steel, platinum or any inert material, is electrically connected to the other terminal of the power source 470 and serves as an anode in the ECD unit 405. In use, the power source 470 supplies a plating current, which causes a bias voltage through the partially completed photovoltaic device 200 and the plating solution 420. The bias voltage may be of any predetermined voltage suitable for an ECD process. Suitable voltage values for an ECD process include values in the range of about −0.3 V to about −10 V. In some embodiments, the ECD bias voltage may be in the range of −0.6 V to −5 V. In other embodiments, the ECD bias voltage may be in the range of −0.9 V and −1.5 V.

The plating current, which is often represented as plating current density (absolute current divided by cathode surface area) may be of a sufficient current to generate the predetermined ECD bias voltage. Thus in the present instance, if the cathode surface area is 1 cm², the platting current density will be in the range of about −0.1 mA/cm² to about −10.0 mA/cm². In some embodiments, the plating current density may be in the range of about −0.1 mA/cm² to about −5.0 mA/cm². In other embodiments, the plating current density may be in the range of about −0.3 mA/cm² to about −3.0 mA/cm². The power source 470 may have a control unit 472 for varying the plating current density or the ECD bias voltage during an ECD process.

The plating solution 420 may contain one or more solute(s) of interest. Solutes of interest may be any suitable material(s) that may be used to form a plated CZT transition layer 145. For example, the solutes of interest may be ions or electrolytes that can be reduced, oxidized, or deposited to form the plated CZT transition layer 145. In this particular instance, the plating solution may include solutes of telluride (Te), cadmium (Cd) and zinc (Zn). When a plating current density and ECD bias are applied to the ECD unit 405, the solutes of interest in the plating solution 420 will be attracted to the partially completed photovoltaic device 200 to form CZT transition layer 145. The plating solution may comprise any appropriate solvent, such as water or a mixture of water and other water-soluble solvents.

The concentrations of each solute can be determined based on the desired composition of the plated CZT transition layer 145. For example, an exemplary plating solution for forming a plated CZT transition layer 145 may have a cadmium ion concentration in the range of 0.001 M to about 10 M, a zinc ion concentration in the range of 0.001 M to about 10 M and a telluride ion concentration in the range of 0.001 M to about 5 M. The plating solution 420 may have a pH of about 0 to about 14. In some embodiments, plating solution 420 has a pH of about 1 to about 7, or about 2 to about 4. In other embodiments, plating solution 420 has a pH of about 7 to about 14, or about 9 to about 12. In still other embodiments, plating solution 420 has a pH of about 5 to about 9, or about 6 to about 8.

ECD unit 405 can function at a predetermined temperature, for example, heater 415 may heat the plating solution 420 to a temperature of about 10° C. to about 100° C., about 10° C. to about 50° C., about 15° C. to about 30° C., about 25° C., or room temperature. During the plating process, power source 470 may generate a plating current density for a predetermined length of time, including about 5 seconds to about 100,000 seconds, about 50 seconds to about 7,500 seconds, about 100 seconds to about 750 seconds, and about 100 seconds to about 500 seconds. The length of time of the plating current density or ECD bias voltage is applied to the ECD unit 405 determines the thickness of the plated CZT transition layer 145.

After plated CZT transition layer 145 is completely formed over the partially completed photovoltaic device 200, the partially completed photovoltaic device 200 may be removed from plating solution 420. Partially completed photovoltaic device 200 may then be washed before additional layers are formed over the CZT transition layer 145.

It is important to recognize that ECD plating variables, such as plating current density, ECD bias voltage, temperature of the plating solution 420 and the composition of the plating solution 420 are what determine the composition of the CZT transition layer 145 as it is formed on the partially completed photovoltaic device 200. Certain variables have been found to favor incorporation of zinc solutes into a plated layer over incorporation of other solutes such as cadmium solutes. Other variables favor incorporation of cadmium solutes into the plated layer over incorporation of other solutes such as zinc solutes. For example, performing the ECD process at a voltage of, for example, about −0.9 V, incorporates a greater proportion of cadmium solutes into the plated layer than zinc solutes. Conversely, performing the ECD process at a voltage of, for example, about −1.2 V, incorporates a greater proportion of zinc solutes into the plated layer than cadmium solutes.

In another example, referring specifically to plating solution composition, the ratio of zinc solutes in the plating solution 420 has a direct correlation to the zinc/cadmium ratio in the plated CZT transition layer 145 deposited over the partially completed photovoltaic device 200. If the zinc solute concentration in the plating solution is increased relative to the cadmium solute concentration in the plating solution, the zinc concentration in the plated CZT transition layer 145 will likewise increase relative to the cadmium concentration in the plated CZT transition layer 145. Conversely, if the cadmium solute concentration in the plating solution is increased relative to the zinc solute concentration in the plating solution, the cadmium concentrate in the plated CZT transition layer 145 may increase relative to the zinc concentration in the plated CZT transition layer 145.

Using the ECD unit 405 to systematically change at least one of these ECD plating variables during an ECD process, changes the composition of the layer being deposited. Further, if the variable is being changed over a time period, the composition of the layer will also change over the same time period. Generally speaking, in order to form a CZT transition layer 145 that consists of one or several Cd(1-x)Zn(x)Te layers where x defines any suitable number between 0 and 1 and the zinc/cadmium mole ratio increases either step-wise or gradually as it gets farther from the partially completed photovoltaic device 200, the initial plating variables may be set such that the initial plating of the CZT transition layer 145 has a composition with a lower ratio of zinc to cadmium and then the ECD plating condition may be changed during the plating process so that the zinc to cadmium ratio increases as it gets farther from partially completed photovoltaic device 200.

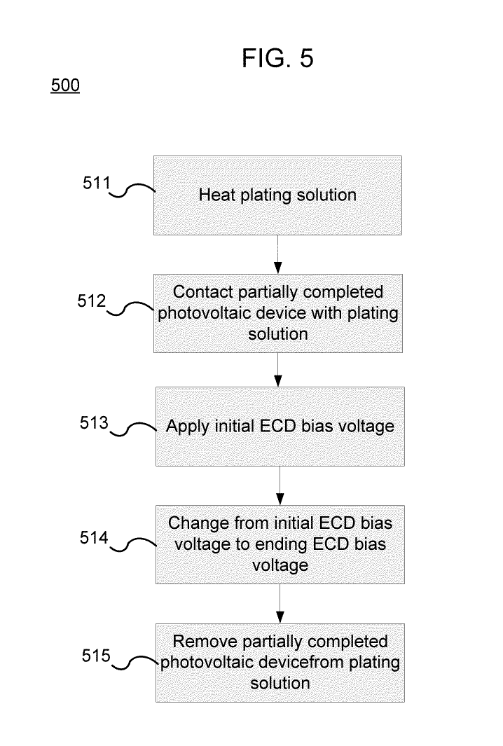

FIG. 5 illustrates a flowchart of a process 500 that may be used to change the composition of a layer being deposited via an ECD plating process with steps 511-515, where an ECD unit 405, as shown in FIG. 4 may be used to change the plating voltage during formation of a CZT transition layer 145 on a partially completed photovoltaic device 200. In step 511, a heater 415 heats a plating solution 420 in container 410 to a predetermined temperature for deposition of a CZT transition layer 145, for example, a temperature in the range of about 10° C. to about 100° C. The plating solution 420 may include, as a solute, cadmium and zinc ions or electrolytes in a predetermined ratio for deposition of a CZT transition layer 145, for example, a zinc solute to cadmium solute ratio in the range of about 1:100 to about 100:1. In step 512, a partially completed photovoltaic device 200, as shown, for example, in FIG. 2, is contacted with the plating solution 420 in container 410. In step 513, power source 470 generates an initial ECD bias voltage that provides a plating current density in the range of, for example, about −0.1 mA/cm² to about −10.0 mA/cm² through partially completed photovoltaic device 200 and plating solution 420. The initial ECD bias voltage is set to favor incorporation of cadmium solutes over zinc solutes in a plated CZT transition layer 145. For example, the initial bias voltage may be −0.9 V. In step 514, the control unit 472 changes the applied ECD bias voltage from the initial ECD bias voltage to an ending ECD bias voltage while maintaining a constant plating current density in the range of, for example, −0.1 mA/cm² to about −10.0 mA/cm². The ending ECD bias voltage is set to favor incorporation of zinc solutes over cadmium solutes in a plated CZT transition layer 145. For example, the ending ECD bias voltage may be −1.2 V. The control unit 472 may change the initial ECD bias voltage to the ending ECD bias voltage in a step-wise fashion or in a gradual fashion. If the ECD bias voltage is changed in a step-wise fashion, then the zinc/mole fraction in the plated CZT transition layer 145 will generally follow the concentration pattern illustrated in FIG. 3A. Alternatively, if the ECD bias voltage is changed in a gradual fashion, then the zinc/mole fraction in the plated CZT transition layer 145 will generally follow the concentration pattern illustrated in FIG. 3B. It should be noted that ECD bias voltages applied during steps 513 and 514, including the initial ECD bias voltage, the final ECD bias voltage and any voltage applied during step-wise or gradual change from the initial ECD bias voltage and the final ECD bias voltage may be any suitable voltage for ECD deposition, for example, any voltage in the range of about −0.3 V to about −10 V. In step 515, the partially completed photovoltaic device 200 with the newly plated CZT transition layer 145 is removed from the plating solution 420.

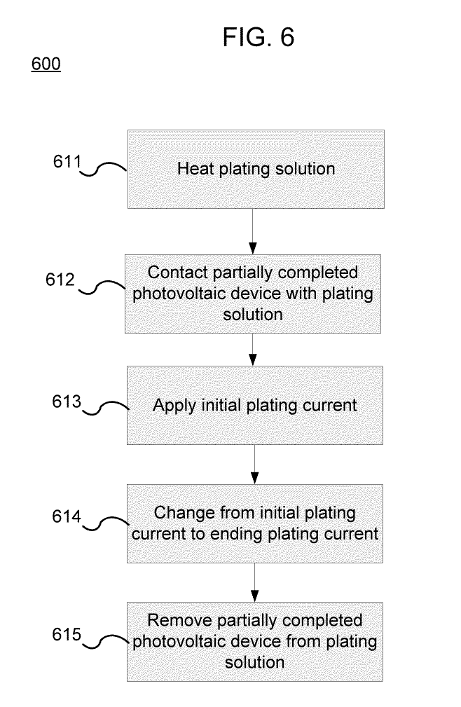

FIG. 6 illustrates another flow chart of an ECD plating process 600 with steps 611-615, where an ECD unit 405, as shown in FIG. 4, may be used to change the plating current density during formation of a CZT transition layer 145 on a partially completed photovoltaic device 200. In step 611, a heater 415 heats the plating solution 420 in a container 410 to a predetermined temperature for deposition of a CZT transition layer 145, for example, a temperature in the range of about 10° C. to about 100° C. The plating solution 420 may include, as a solute, cadmium and zinc ions or electrolytes in a predetermined ratio for deposition of a CZT transition layer 145, for example, a zinc solute to cadmium solute ratio in the range of about 1:100 to about 100:1. In step 612, a partially completed photovoltaic device 200, as shown, for example, in FIG. 2, is contacted with a plating solution 420 in container 410. In step 613, power source 470 generates an initial plating current density with an ECD bias voltage in the range of, for example, −0.3 V to about −10 V through the partially completed photovoltaic device 200 and the plating solution 420. The initial plating current density is set to favor incorporation of cadmium solutes over zinc solutes in a plated CZT transition layer 145. For example, the initial plating current density may be −0.5 mA/cm2. In step 614, the control unit 472 changes the plating current density from the initial plating current density to an ending plating current density that favors incorporation of zinc solutes over cadmium solutes in a plated CZT transition layer 145 while maintaining a constant ECD bias voltage of, for example, −1.0 V to about −10 V. For example, the ending plating current density may be −1.0 mA/cm². The control unit 472 may change the initial plating current density to the ending plating current density in a step-wise fashion or in a gradual fashion. If the plating current density is changed in a step-wise fashion, then the zinc/mole fraction in the plated CZT transition layer 145 will generally follow the concentration pattern illustrated in FIG. 3A. Alternatively, if the plating current density is changed in a gradual fashion, then the zinc/mole fraction in the plated CZT transition layer 145 will generally follow the concentration pattern illustrated in FIG. 3B. It should be noted that the plating current density applied during steps 613 and 614, including the initial plating current density, the final plating current density and any plating current density applied during the step-wise or gradual change from the initial plating current density and the final plating current density may be any plating current density sufficient for ECD deposition, for example, any plating current density in the range of about −0.1 mA/cm² to about −10.0 mA/cm². In step 615, the partially completed photovoltaic device 200 with the newly plated CZT transition layer 145 is removed from the plating solution 420.

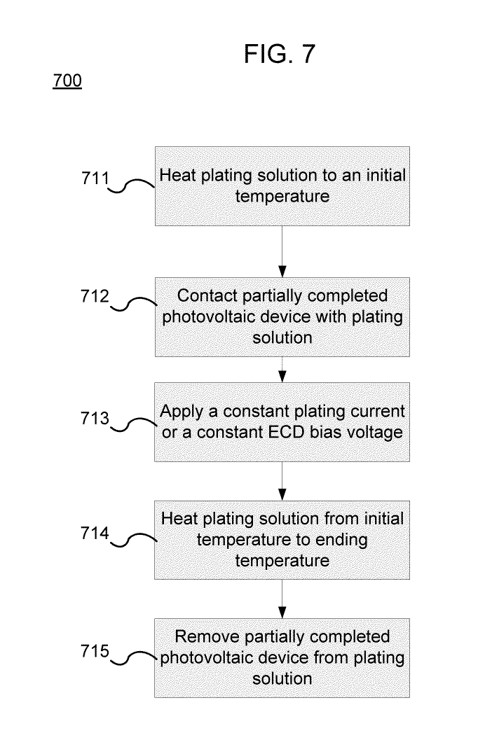

FIG. 7 illustrates another flow chart of an ECD plating process 700 with steps 711-715, where an ECD unit 405, as shown in FIG. 4, may be used to change the temperature of plating solution 420 during formation of a CZT transition layer 145 on a partially completed photovoltaic device 200. In step 711, a heater 415 heats a plating solution 420 in a container 410 to an initial temperature that favors incorporating cadmium solutes over zinc solutes in a CZT transition layer 145. For example, the initial temperature of the plating solution 420 may be in the range of about 10° C. to about 40° C. The plating solution 420 may include, as a solute, cadmium and zinc ions or electrolytes in a predetermined ratio for deposition of a CZT transition layer 145, for example, a zinc solute to cadmium solute ratio in the range of about 1:100 to about 100:1. In step 712, a partially completed photovoltaic device 200, as shown, for example, in FIG. 2, is contacted with a plating solution 420 in the container 410. In step 713, power source 470 generates an ECD bias voltage, for example, in the range of about −0.3 V to about −10 V and corresponding plating current density, for example, in the range of −0.1 mA/cm² to about −10.0 mA/cm², through the partially completed photovoltaic device 200 and the plating solution 420. In step 714, the heater 415 increases the heat applied to the plating solution 420 so that the plating solution temperature increases from the initial temperature to an ending temperature that favors incorporation of zinc solutes over cadmium solutes in a plated CZT transition layer 145, for example, a temperature in the range of about 70° C. to about 100° C. The initial temperature of the plating solution 420 may be changed to the ending temperature of the plating solution 420 in a step-wise fashion or in a gradual fashion. If the temperature of the plating solution 420 is changed in a step-wise fashion, then the zinc/mole fraction in the plated CZT transition layer 145 will generally follow the concentration pattern illustrated in FIG. 3A. Alternatively, if the temperature of the plating solution 420 is changed in a gradual fashion, then the zinc/mole fraction in the plated CZT transition layer 145 will generally follow the concentration pattern illustrated in FIG. 3B. It should be noted that the temperature of the plating solution 420 used during steps 612 and 614, including the initial temperature of the plating solution 420, the final temperature of the plating solution 420 and any temperature of the plating solution 420 used during the step-wise or gradual change from the initial to the final temperature of the plating solution 420, may be any temperature suitable for ECD deposition, for example, any temperature in the range of about 10° C. to about 100° C. In step 715, the partially completed photovoltaic device 200 with the newly plated CZT transition layer 145 is removed from the plating solution 420.

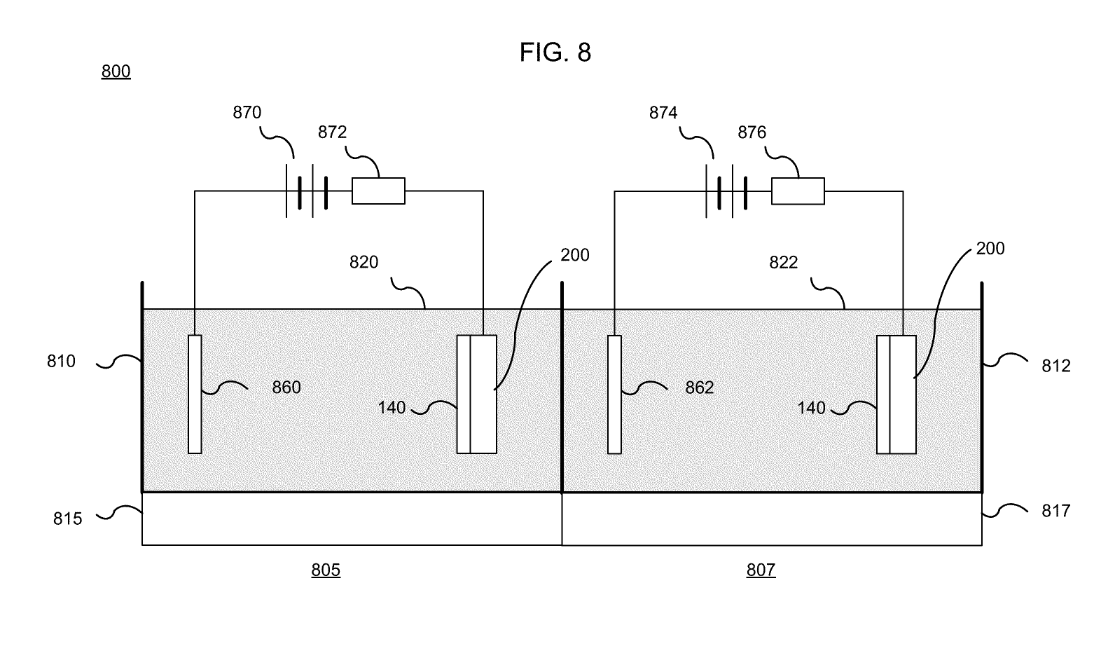

In other embodiments, it may be desirable to use multiple plating solutions having different compositions to change the composition of the CZT transition layer 145 as it is formed on a partially completed photovoltaic device 200. FIG. 8 shows an ECD system 800 which may include multiple ECD units 805, 807. As described with reference to the single ECD unit 405 shown in FIG. 4, first and second ECD units 805, 807 may include first and second containers 810, 812, first and second heaters 815, 817 positioned under or around, attached or detached from the first and second containers 810, 812 respectively and first and second plating solutions 820, 822 in first and second containers 810, 812 respectively. First and second ECD units 805, 807 may be used in combination to form a CZT transition layer 145 over a partially completed photovoltaic device 200.

When contacted with the first plating solution 820, partially completed photovoltaic device 200 is electrically connected to a first power source 870, which may have a positive terminal and a negative terminal. The partially completed photovoltaic device 200 is electrically connected to the negative terminal of the first power source 870 and may act as a cathode in first ECD unit 805. A first complementary electrode 860, which may be made of any appropriate electrode material known in the art, is electrically connected to the positive terminal of the first power source 870 and may act as an anode in the first ECD unit 805. In use, the first power source 870 supplies a plating current density, which causes an external ECD bias voltage through partially completed photovoltaic device 200 and first plating solution 820. The first power source 870 may have a first control unit 872 capable of adjusting or changing the plating current density or the ECD bias voltage through the partially completed photovoltaic device 200 and the first plating solution 820 during the plating process. Solutes of interest are attracted from first plating solution 820 to partially completed photovoltaic device 200 and form a first portion of the CZT transition layer 145 over the partially completed photovoltaic device 200. Then the partially completed photovoltaic device 200 is removed from first plating solution 820 and contacted with second plating solution 822.

When contacted with the second plating solution 822, partially completed photovoltaic device 200 is electrically connected to a second power source 874, which may have a positive terminal and a negative terminal. The partially completed photovoltaic device 200 is electrically connected to the negative terminal of the second power source 874 and may act as a cathode in second ECD unit 805. A second complementary electrode 862, which may be made of any appropriate electrode material known in the art, is electrically connected to the positive terminal of the second power source 874 and may act as an anode in the second ECD unit 805. In use, the second power source 874 supplies a plating current density, which causes an external ECD bias voltage through partially completed photovoltaic device 200 and second plating solution 822. The second power source 874 may have a second control unit 876 capable of adjusting or changing the plating current density or the ECD bias voltage through the partially completed photovoltaic device 200 and the second plating solution 822 during the plating process. Solutes of interest are attracted from the second plating solution 822 to partially completed photovoltaic device 200 and form a second portion of the CZT transition layer 145 over the partially completed photovoltaic device 200. Then the partially completed photovoltaic device 200 is removed from the second plating solution 822.

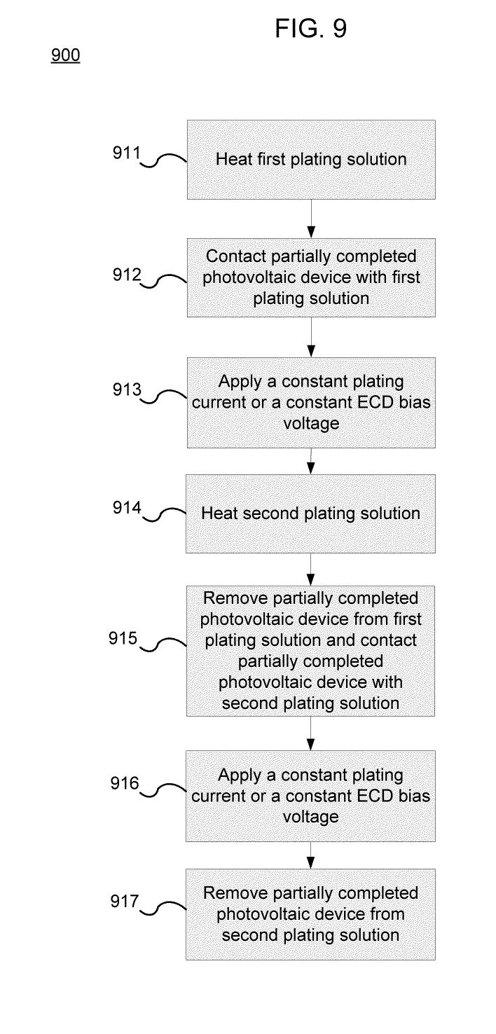

FIG. 9 illustrates a flow chart of an ECD plating process 900 with steps 911-917, where an ECD system 800, as shown in FIG. 8, may be used to change the composition of the plated CZT transition layer 145. In step 911, first heater 815 heats the first plating solution 820 in a first container 810 to a predetermined temperature for deposition of a CZT transition layer 145, for example, a temperature in the range of about 10° C. to about 100° C. First plating solution 820 may include, as a solute, cadmium and zinc ions or electrolytes in a predetermined ratio for deposition of a CZT transition layer 145, for example, a zinc solute to cadmium solute ratio in the range of about 1:100 to about 100:1. The ratio of zinc solutes to cadmium solutes in the first plating solution 820 is set to favor incorporation of cadmium solutes over zinc solutes in a CZT transition layer 145, for example, a 1:2 ratio of zinc to cadmium solutes, respectively. In step 912, partially completed photovoltaic device 200, as shown, for example, in FIG. 2, is contacted with the first plating solution 820 in a first container 810. In step 913, first power source 870 generates a suitable ECD bias voltage, for example, in the range of about −0.3 V to about −10 V and corresponding plating current density, for example, in the range of −0.1 mA/cm² to about −10.0 mA/cm², through the partially completed photovoltaic device 200 and the first plating solution 820.

In step 914, second heater 817 heats the second plating solution 822 to a predetermined temperature for deposition of a CZT transition layer 145, for example, a temperature in the range of about 10° C. to about 100° C. Second plating solution 822 may include, as a solute, cadmium and zinc ions or electrolytes in a predetermined ratio that is set to favor incorporation of zinc solutes over cadmium solutes in a plated CZT transition layer 145, for example, a 2:1 ratio of zinc to cadmium solutes, respectively. In step 915, the partially completed photovoltaic device 200 is removed from the first plating solution 820 and contacted with a second plating solution 822. In step 916, a second power source 874 generates an ECD bias voltage, for example, in the range of about −0.3 V to about −10 V and corresponding plating current density, for example, in the range of −0.1 mA/cm² to about −10.0 mA/cm² through the partially completed photovoltaic device 200 and the second plating solution 822. Depositing the CZT transition layer 145 using multiple plating baths with different plating solution compositions changes the composition of the CZT transition layer 145 in a step-wise fashion where the zinc/mole fraction in the zinc cadmium telluride layer will generally follow the concentration pattern illustrated in FIG. 3A. It should be noted that although steps 911-916 describe using only two separate plating baths, any desirable number of plating baths with different plating solution compositions may be used to provided the desired steps of composition in the plated CZT transition layer 145 and the steps of distinct composition in the plated CZT transition layer 145 will correspond to the number of baths used in the plating process. In step 917, the partially completed photovoltaic device 200 with the newly plated CZT transition layer 145 is removed from the second plating solution 822.

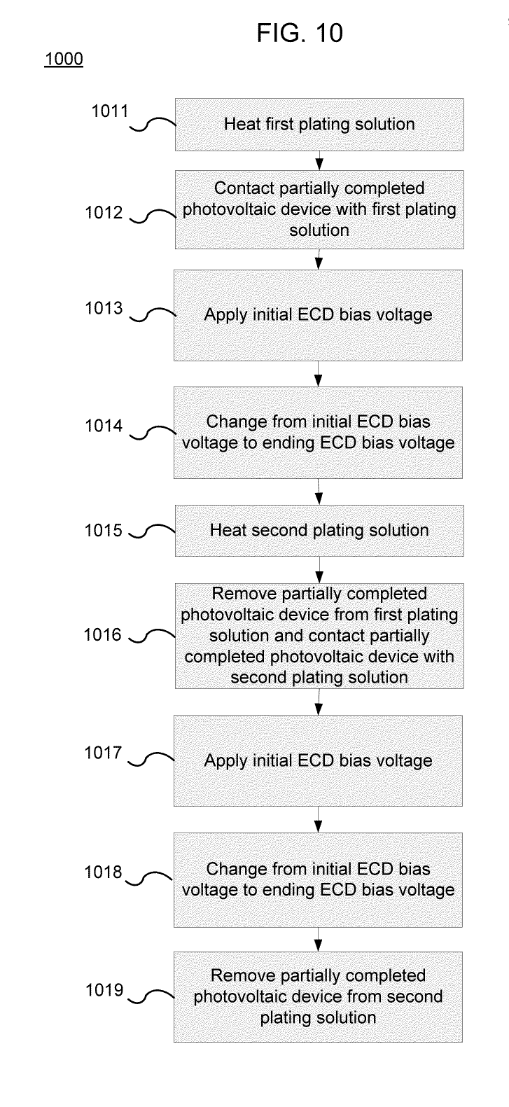

In other embodiments, ECD plating system 800 may be used to change the composition of a plated CZT transition layer 145 as it is deposited on a partially completed photovoltaic device 200 by using multiple plating solutions in combination with changing other plating variables, for example, the plating voltage, plating current density or plating bath temperature as described respectively in reference to ECD plating processes 500, 600, and 700. For example, FIG. 10 illustrates another flow chart of an ECD plating process 1000 with steps 1011-1019, where an ECD system 800, as shown in FIG. 8, may be used to change the composition of a plated CZT transition layer 145. In step 1011, a first heater 815 heats the first plating solution 820 to a predetermined temperature for deposition of a CZT transition layer 145, for example, a temperature in the range of about 10° C. to about 100° C. First plating solution 820 may include, as a solute, cadmium and zinc ions or electrolytes in a predetermined ratio for deposition of a CZT transition layer 145, for example, a zinc solute to cadmium solute ratio in the range of about 1:100 to about 100:1. The ratio of zinc solutes to cadmium solutes in the first plating solution 820 is set to favor incorporation of cadmium solutes over zinc solutes in a CZT transition layer 145, for example, a 1:2 ratio of zinc to cadmium solutes, respectively. In step 1012, a partially completed photovoltaic device 200, as shown in FIG. 2, is contacted with a first plating solution 820 in a first container 810. In step 1013, a first power source 870 generates an initial ECD bias voltage with a plating current density in the range of −0.1 mA/cm² to about −10.0 mA/cm² through partially completed photovoltaic device 200 and first plating solution 820. The initial ECD bias voltage is set to favor incorporation of cadmium solutes over zinc solutes in a plated CZT transition layer 145. For example, the initial bias voltage may be −0.9 V. In step 1014, the first control unit 872 changes the applied ECD bias voltage from the initial ECD bias voltage to an ending ECD bias voltage that favors incorporation of zinc solutes over cadmium solutes in a plated CZT transition layer 145 while maintaining a constant plating current density in the range of, for example, −0.1 mA/cm² to about −10.0 mA/cm². For example, the ending ECD bias voltage may be −1.2 V.

In step 1015, a second heater 815 heats the second plating solution 822 to a predetermined temperature for deposition of a CZT transition layer 145, for example, a temperature in the range of about 10° C. to about 100° C. Second plating solution 822 may include, as a solute, cadmium and zinc ions or electrolytes in a predetermined ratio that is set to favor incorporation of zinc solutes over cadmium solutes in a plated CZT transition layer 145, for example, a 2:1 ratio of zinc to cadmium solutes, respectively. In step 1016, the partially completed photovoltaic device 200 is removed from the first plating solution 820 and contacted with a second plating solution 822 In step 1017, a second power source 874 generates an initial ECD bias voltage with a plating current density in the range of about −0.1 mA/cm² to about −10.0 mA/cm² through partially completed photovoltaic device 200 and second plating solution 822. The initial ECD bias voltage is set to favor incorporation of cadmium solutes over zinc solutes in a plated CZT transition layer 145. For example, the initial bias voltage may be −0.9 V. In step 1018, the second control unit 876 changes the applied ECD bias voltage from the initial ECD bias voltage to an ending ECD bias voltage that favors incorporation of zinc solutes over cadmium solutes in a plated CZT transition layer 145 while maintaining a constant plating current density in the range of, for example, about −0.1 mA/cm² to about −10.0 mA/cm². For example, the ending ECD bias voltage may be −1.2 V. In step 1019, the partially completed photovoltaic device 200 with the newly plated CZT transition layer 145 is removed from the second plating solution 822.

It should be noted that depositing the CZT transition layer 145 using a combination of multiple plating baths with different plating solution compositions and changing the plating voltage in the two baths may be configured to produced step-wise or a gradual composition change in the plated CZT transition layer 145. If the multiple baths and changing the ECD bias voltage are configured to provide step-wise composition changes, then the zinc/mole fraction in the plated CZT transition layer 145 will generally follow the concentration pattern illustrated in FIG. 3A. Alternatively, if the multiple baths and changing the ECD bias voltage are configured to provide a gradual composition change, then the zinc/mole fraction in the plated CZT transition layer will generally follow the concentration pattern illustrated in FIG. 3B.

The embodiments described above are offered by way of illustration and example. It should be understood that the examples provided above may be altered in certain respects and still remain within the scope of the claims. It should be appreciated that, while the invention has been described with reference to the above exemplary embodiments, other embodiments are within the scope of the claims.

What is claimed as new and desired to be protected by Letters Patent of the United States is:

1. A method of manufacturing a photovoltaic device, the method comprising:
forming a partially completed photovoltaic device with at least a first semiconductor layer of a first semiconductor material;
forming a semiconductor interface layer of a mixture containing the first semiconductor material and a second semiconductor material on the first semiconductor layer using electrochemical deposition; and
changing the composition of the formed semiconductor interface layer during the electrochemical deposition.

2. The method of claim 1, wherein forming the semiconductor interface layer further comprising forming the semiconductor interface layer with a first material to second material mole ratio of about (1-x):x, where x defines a number from 0 to 1, which changes in a thickness direction of the semiconductor interface layer.

3. The method of claim 2, wherein the semiconductor interface layer is a cadmium zinc telluride layer.

4. The method of claim 3, wherein forming the semiconductor interface layer further comprises:
contacting at least one surface of the first semiconductor layer of the partially completed photovoltaic device with a plating solution;
electrically connecting the partially completed photovoltaic device to a power source;
forming a plated cadmium zinc telluride layer on the first semiconductor layer during a predetermined electrochemical deposition period of time; and
changing the composition of the plated cadmium zinc telluride layer as it is formed on the first semiconductor layer by changing at least one set plating variable during the predetermined period of time, wherein the set plating condition is one or more of the following:
a composition of the plating solution contacted with the first semiconductor layer;
a temperature of the plating solution contacted with the first semiconductor layer;
a plating current density generated by the power source through the partially completed photovoltaic device and the plating solution when forming the plated cadmium zinc telluride layer; and
a bias voltage created by the plating current density through the partially completed photovoltaic device and the plating solution when forming the plated cadmium zinc telluride layer.

5. The method of claim 4, wherein the composition of the plating solution contacted with the first semiconductor layer includes solutes of cadmium (Cd), zinc (Zn) and telluride (Te).

6. The method of claim 4, wherein the temperature of the plating solution is in a range of about 10° C. to about 100° C.

7. The method, of claim 4, wherein the plating current density generated by the power source is in a range of about −0.1 mA/cm² to about −10.0 mA/cm².

8. The method of claim 4, wherein the bias voltage created by the plating current density through the partially completed photovoltaic device and the plating solution is in a range of about −0.3 V to about −10 V.

9. The method of claim 6, wherein the composition of the plated cadmium zinc telluride layer is changed as it is formed on the first semiconductor layer by changing the temperature of the plating solution contacted with the first semiconductor layer.

10. The method of claim 9, wherein changing the temperature of the plating solution comprises changing the plating solution from a first set temperature in a range of about 10° C. to about 40° C. to a second set temperature in a range of about 70° C. to about 100° C. during the predetermined period of time for forming the plated cadmium zinc telluride layer on the first semiconductor layer.

11. The method of claim 10, wherein the temperature of the plating solution is changed in a step-wise or in a gradual fashion.

12. The method of claim 7, wherein the composition of the plated cadmium zinc telluride layer is changed as it is formed on the first semiconductor layer by changing the plating current density.

13. The method of claim 12, wherein changing the plating current density comprises changing the plating current density from a first set plating current density of about −0.5 mA/cm² to a second set plating current density of about −1.0 mA/cm² during the predetermined period of time for forming the plated cadmium zinc telluride layer on the first semiconductor layer.

14. The method of claim 13, wherein the plating current density is changed in a step-wise or in a gradual fashion.

15. The method of claim 8, wherein the composition of the plated cadmium zinc telluride layer is changed as it is formed on the first semiconductor layer by changing the bias voltage through the partially completed photovoltaic device and the plating solution.

16. The method of claim 15, wherein changing the bias voltage comprises changing the bias voltage from a first set bias voltage of about −0.9 V to a second set bias voltage of about −1.2 V during the predetermined period of time for forming the plated cadmium zinc telluride layer on the first semiconductor layer.

17. The method of claim 16, wherein the bias voltage is changed in a step-wise or in a gradual fashion.

18. The method of claim 3, wherein forming the semiconductor interface layer further comprises:
contacting at least one surface of the first semiconductor layer of the partially completed photovoltaic device with a first plating solution;
electrically connecting the partially completed photovoltaic device to a first power source;
forming a first portion of a plated cadmium zinc telluride layer on the first semiconductor layer during a first predetermined period of time;
removing the partially completed photovoltaic device from the first plating solution;
contacting the at least one surface of the first semiconductor layer of the partially completed photovoltaic device with a second plating solution;
electrically connecting the partially completed photovoltaic device to a second power source; and
forming a second portion of the plated cadmium zinc telluride layer on the first semiconductor layer during a second predetermined period of time.

19. The method of claim 18, wherein the first and second plating solutions include solutes of cadmium (Cd), zinc (Zn) and telluride (Te) and wherein the first and second plating solutions have different compositions.

20. The method of claim 19, wherein the first plating solution has a higher concentration ratio of cadmium solutes to zinc solutes than the second plating solution.

21. The method of claim 20, further comprising:
changing the composition of the first portion of the plated cadmium zinc telluride layer as it is formed on the first semiconductor layer by changing at least one set plating condition during the first predetermined period of time, wherein the set plating condition is one or more of the following:
a temperature of the first plating solution contacted with the first semiconductor layer;
a plating current density generated by the first power source through the partially completed photovoltaic device and the first plating solution when forming the first portion of the plated cadmium zinc telluride layer; and
a bias voltage created by the plating current density through the partially completed photovoltaic device and the first plating solution when forming the first portion of the plated cadmium zinc telluride layer; and
changing the composition of the second portion of the plated cadmium zinc telluride layer as it is formed on the first semiconductor layer by changing at least one set plating condition during the second predetermined period of time, wherein the set plating condition is one or more of the following:
a temperature of the second plating solution contacted with the first semiconductor layer;
a plating current density generated by the second power source through the partially completed photovoltaic device and the second plating solution when forming the second portion of the plated cadmium zinc telluride layer; and
a bias voltage created by the plating current density through the partially completed photovoltaic device and the second plating solution when forming the second portion of the plated cadmium zinc telluride layer.

22. An electrochemical deposition system comprising:
a partially completed photovoltaic device having a first semiconductor layer of a first semiconductor material; and
an electrochemical deposition apparatus for forming a semiconductor interface layer of a mixture containing the first semiconductor material and a second semiconductor material on the first semiconductor layer, wherein the electrochemical deposition apparatus is configured to change the composition of the semiconductor interface layer during a deposition process.

23. The system of claim 22, wherein the semiconductor interface layer has a first material to second material mole ratio of about (1-x):x, where x defines a number from 0 to 1, which changes in a thickness direction of the semiconductor interface layer.

24. The system of claim 23, wherein the semiconductor interface layer is a cadmium zinc telluride layer.

25. The system of claim 24, wherein the electrochemical deposition apparatus comprises:
a plating bath;
a plating solution in the plating bath for contacting the first semiconductor layer of the partially completed photovoltaic device;
a heater below the plating bath for heating the plating solution to a predetermined temperature;
a power source electrically connected to the partially completed photovoltaic device for generating a plating current density that causes a bias voltage through the partially completed photovoltaic device when it is in contact with the plating solution; and
a power control unit coupled to the power source for adjusting the plating current density generated by the power source or the bias voltage through the partially completed photovoltaic device and the plating solution caused by the plating current density; and
wherein the electrochemical deposition apparatus is configured to change the composition of the plated cadmium zinc telluride layer as it is formed on the first semiconductor layer by changing the temperature of the plating solution, the plating current density generated by the power source or the bias voltage created by the plating current density while forming the plated cadmium zinc telluride layer on the first semiconductor layer.

26. The system of claim 25, wherein the composition of the plating solution contacting the first semiconductor layer includes solutes of cadmium(Cd), zinc(Zn) and telluride(Te).

27. The system of claim 25, wherein the heater heats the plating solution to a temperature in a range of about 10° C. to about 100° C.

28. The system of claim 25, wherein the power source generates the plating current density in a range of about −0.1 mA/cm² to about −10.0 mA/cm².

29. The system of claim 25, wherein the bias voltage created by the plating current density through the partially completed photovoltaic device and the plating solution is in a range of about −0.3 V to about −10 V.

30. The system of claim 27, wherein the electrochemical deposition apparatus is configured to change the composition of the plated cadmium zinc telluride layer as it is formed on the first semiconductor layer by changing the temperature of the plating solution contacted with the first semiconductor layer.

31. The system of claim 30, wherein the heater is configured to heat the plating solution from a first set temperature to a second set temperature during the predetermined period of time for forming the plated cadmium zinc telluride layer on the first semiconductor layer.

32. The system of claim 31, wherein the heater is configured to heat the plating solution in a step-wise or in a gradual fashion.

33. The system of claim 28, wherein the electrochemical deposition apparatus is configured to change the composition of the plated cadmium zinc telluride layer as it is formed on the first semiconductor layer by changing the plating current density.

34. The system of claim 33, wherein the power control unit is configured to change the plating current density generated by the power source from a first set plating current density to a second set plating current density during the predetermined period of time for forming the plated cadmium zinc telluride layer on the first semiconductor layer.

35. The system of claim 34, wherein the power control unit is configured to change the plating current density in a step-wise or in a gradual fashion.

36. The system of claim 29, wherein the electrochemical deposition apparatus is configured to change the composition of the plated cadmium zinc telluride layer as it is formed on the first semiconductor layer by changing the bias voltage caused by the plating current density.

37. The system of claim 36, wherein the power control unit is configured to change the bias voltage caused by the plating current density from a first set bias voltage to a second set bias voltage during the predetermined period of time for forming the plated cadmium zinc telluride layer on the first semiconductor layer.

38. The system of claim 37, wherein the power control unit is configured to change the bias voltage in a step-wise or in a gradual fashion.

39. The system of claim 24, wherein the electrochemical deposition apparatus comprises:
a first electrochemical deposition unit for forming a first portion of a plated cadmium zinc telluride layer on the first semiconductor layer over a first predetermined period of time, wherein the first electrochemical deposition unit comprises:
a first plating bath;
a first plating solution in the first plating bath for contacting the first semiconductor layer;
a first heater below the first plating bath for heating the first plating solution to a predetermined temperature;
a first power source electrically connected to the partially completed photovoltaic device for generating a plating current density that causes a bias voltage through the partially completed photovoltaic device when it is in contact with the first plating solution; and
a first power control unit coupled to the first power source for adjusting the plating current density generated by the first power source or the bias voltage through the partially completed photovoltaic device and the first plating solution caused by the plating current density; and
a second electrochemical deposition unit for forming a second portion of the plated cadmium zinc telluride layer on the first semiconductor layer over a second predetermined period of time, wherein the second electrochemical deposition unit comprises:
a second plating bath;
a second plating solution in the second plating bath for contacting the first semiconductor layer;
a second heater below the second plating bath for heating the second plating solution to a predetermined temperature;
a second power source electrically connected to the partially completed photovoltaic device for generating a plating current density that causes a bias voltage through the partially completed photovoltaic device when it is in contact with the second plating solution; and
a second power control unit coupled to the second power source for adjusting the plating current density generated by the second power source or the bias voltage through the partially completed photovoltaic device and the second plating solution caused by the plating current density.

40. The system of claim 39, wherein the first and second plating solutions include solutes of cadmium (Cd), zinc (Zn) and telluride (Te) and wherein the first and second plating solutions have different compositions.

41. The system of claim 40, wherein the first plating solution has a higher concentration ratio of cadmium solutes to zinc solutes than the second plating solution.

42. The system of claim 39, wherein the first electrochemical deposition unit is configured to change the composition of the first portion of the plated cadmium zinc telluride layer as it is formed on the first semiconductor layer by changing the temperature of the first plating solution, the plating current density generated by the first power source or the bias voltage created by the plating current density while forming the first portion of the plated cadmium zinc telluride layer on the first semiconductor layer; and
wherein the second electrochemical deposition unit is configured to change the composition of the second portion of the plated cadmium zinc telluride layer as it is formed on the first semiconductor layer by changing the temperature of the second plating solution, the plating current density generated by the second power source or the bias voltage created by the plating current density while forming the second portion of the plated cadmium zinc telluride layer on the first semiconductor layer.
